(19) United States
(12) Patent Application Publication
(10) Pub. No.: US 2026/0113970 A1
(43) Pub. Date: Apr. 23, 2026

(54) SEMICONDUCTOR DEVICE INCLUDING TWO DIMENSIONAL MATERIAL AND METHOD FOR FABRICATING THE SAME

(71) Applicant: Samsung Electronics Co., Ltd., Suwon-si (KR)

(72) Inventors: Jin Won MA, Suwon-si (KR); Sang Min KANG, Suwon-si (KR); Sung-Hwan JANG, Suwon-si (KR)

(73) Assignee: Samsung Electronics Co., Ltd., Suwon-si (KR)

(21) Appl. No.: 19/241,670

(22) Filed: Jun. 18, 2025

(30) Foreign Application Priority Data
Oct. 18, 2024 (KR) 10-2024-0143140

(51) Int. Cl. H10D 30/47; H10D 30/01

(52) U.S. Cl. CPC H10D 30/481; H10D 30/017

(57) ABSTRACT

A semiconductor device may include a semiconductor layer including a two-dimensional semiconductor material and an electrode layer on the semiconductor layer. The electrode layer may include a first impurity pile-up region in which impurities are gathered.

### CROSS-REFERENCE TO RELATED APPLICATIONS

This application claims priority from Korean Patent Application No. 10-2024-0143140, filed on Oct. 18, 2024 in the Korean Intellectual Property Office, and all the benefits accruing therefrom under 35 U.S. C. 119, the entire contents of which are herein incorporated by reference.

### BACKGROUND OF THE DISCLOSURE

The present disclosure relates to a semiconductor device including a two-dimensional semiconductor material and/or a method for fabricating the same.

A transistor is a semiconductor device that serves to perform electrical switching, and is used in various semiconductor products such as a memory and a driver IC. When the size of the semiconductor device becomes smaller, the number of semiconductor devices that may be integrated on one wafer may increase and an operating speed of the semiconductor device also may increase. Research for reducing the size of the semiconductor devices is actively progressing.

In recent years, research for using two-dimensional materials has been progressing as a proposal for reducing the size of the semiconductor devices. Because the two-dimensional materials may have stable and excellent properties even at a thin thickness of 1 nm or less, the two-dimensional materials are in the spotlight as materials that may overcome the limit of performance degradation caused by the reduction in size of semiconductor devices.

### SUMMARY OF THE DISCLOSURE

Aspects of the present disclosure provide a semiconductor device including a two-dimensional semiconductor material.

Aspects of the present disclosure also provide a method for fabricating a semiconductor device including a two-dimensional semiconductor material.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an example embodiment of the present disclosure, a semiconductor device may include a semiconductor layer including a two-dimensional semiconductor material; and an electrode layer on the semiconductor layer. The electrode layer may include a first impurity pile-up region in which impurities are gathered.

According to an example embodiment of the present disclosure, a method for fabricating a semiconductor device may include forming a semiconductor layer including a two-dimensional semiconductor material; implanting impurities onto the semiconductor layer; and forming a capping layer which covers the semiconductor layer into which the impurities are implanted.

According to an example embodiment of the present disclosure, a semiconductor device may include a semiconductor layer including a two-dimensional semiconductor material; a first conductive layer on the semiconductor layer; a second conductive layer on the semiconductor layer; a first silicide layer between the semiconductor layer and the first conductive layer; and a second silicide layer between the semiconductor layer and the second conductive layer. The first silicide layer may include a first impurity pile-up region along an interface between the semiconductor layer and the first silicide layer. The second silicide layer may include a second impurity pile-up region along an interface between the semiconductor layer and the second silicide layer.

### BRIEF DESCRIPTION OF THE DRAWINGS

The above and other aspects and features of the present disclosure will become more apparent by describing in detail example embodiments thereof referring to the attached drawings, in which:

FIG. 1 is a diagram for explaining a semiconductor device according to some embodiments;

FIG. 2 is a diagram for explaining first to third impurity pile-up regions of FIG. 1;

FIG. 3 is a diagram for explaining a semiconductor device according to some embodiments;

FIGS. 4 to 7 are diagrams for explaining a method for fabricating a semiconductor device according to some embodiments;

FIG. 8 is diagram for explaining a method for fabricating a semiconductor device according to some embodiments;

FIG. 9 is diagram for explaining an electronic element according to some embodiments;

FIG. 10 is diagram for explaining an electronic system according to some embodiments;

FIG. 11 is diagram for explaining an electronic system according to some embodiments; and

FIG. 12 is diagram for explaining a neuromorphic device according to some embodiments.

### DETAILED DESCRIPTION OF THE EMBODIMENTS

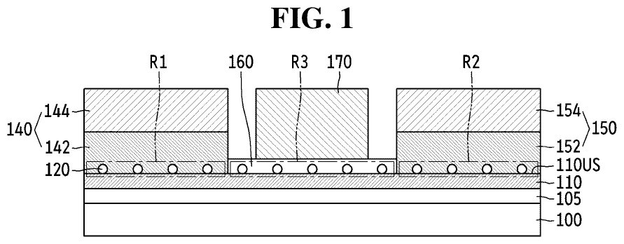

FIG. 1 is a diagram for explaining a semiconductor device according to some embodiments.

Referring to FIG. 1, the semiconductor device according to some embodiments may include a substrate 100, an insulating layer 105, a semiconductor layer 110, a first electrode layer 140, a second electrode layer 150, a gate oxide layer 160, and a gate electrode 170.

The substrate 100 may include a semiconductor material. The substrate 100 may include a compound semiconductor substrate or an elemental semiconductor substrate. The substrate 100 may include, for example, silicon (Si), germanium (Ge), silicon germanium (SiGe), silicon carbide (SiC), gallium arsenide (GaAs), indium arsenide (InAs), indium phosphide (InP), and the like. In addition, the substrate 100 may further include an insulating material, such as an oxide, silicon nitride, or silicon oxynitride. The substrate 100 may be doped with P-type impurities or N-type impurities.

The insulating layer 105 may be disposed on the substrate 100. The insulating layer 105 may be disposed between the substrate 100 and the semiconductor layer 110. The substrate 100 and the semiconductor layer 110 may be insulated by the insulating layer 105. The insulating layer 105 may include, for example, silicon oxide.

The semiconductor layer 110 may be disposed on the insulating layer 105. The semiconductor layer 110 includes a two-dimensional material having a two-dimensional crystal structure. The two-dimensional material may have a layered structure of a monolayer or multilayers. Each layer constituting the two-dimensional material may have a thickness of an atomic level. For example, the semiconductor layer 110 may include graphene, TMD (Transition Metal Dichalcogenide), black phosphorus, or hBN (hexagonal Boron-Nitride).

The TMD may include, for example, one transition metal among Mo, W, Nb, V, Ta, Ti, Zr, Hf, Tc, and Re, and one chalcogen element among S, Se, and Te. The TMD may be represented, for example, as MX₂, here M represents a transition metal, and X represents a chalcogen element. For example, M may be Mo, W, Nb, V, Ta, Ti, Zr, Hf, Tc, Re, etc., and X may be S, Se, Te, etc. Thus, for example, the TMD may include MoS₂, MoSe₂, MoTe₂, WS₂, WSe₂, WTe₂, ZrS₂, ZrSe₂, HfS₂, HfSe₂, NbSe₂, ReSe₂, etc. Alternatively, the TMD may not be expressed as MX₂. In this case, for example, the TMD may include CuS, which is a compound of Cu which is a transition metal and S which is a chalcogen element. On the other hand, the TMD may be a chalcogenide material including a non-transition metal. The non-transition metal may include, for example, Ga, In, Sn, Ge, Pb, etc. In this case, the TMD may include a compound of a non-transition metal such as Ga, In, Sn, Ge and Pb, and a chalcogen element such as S, Se and Te. For example, the TMD may include SnSe₂, GaS, GaSe, GaTe, GeSe, In₂Se₃, InSnS₂, etc.

The first electrode layer 140 and the second electrode layer 150 may be disposed on the semiconductor layer 110 and may be spaced apart from each other. The first electrode layer 140 may be disposed at one end of the semiconductor layer 110, and the second electrode layer 150 may be disposed at the other end of the semiconductor layer 110. The first electrode layer 140 and the second electrode layer 150 may be in contact with the semiconductor layer 110. For example, at least a portion of a bottom face of the first electrode layer 140 and at least a part of the bottom face of a second electrode layer 150 may be in contact with the semiconductor layer 110. The first electrode layer 140 may be a source electrode, and the second electrode layer 150 may be a drain electrode.

The first electrode layer 140 may include a first silicide layer 142 and a first conductive layer 144. The first silicide layer 142 may be disposed between the semiconductor layer 110 and the first conductive layer 144. The electrical resistance of the first silicide layer 142 may be smaller than the electrical resistance of the first conductive layer 144. Therefore, the speed of movement of carriers (e.g., electrons or holes) through the semiconductor layer 110 may be faster than when the first conductive layer 144 is in direct contact with the semiconductor layer 110. In addition, by providing the first silicide layer 142, the contact resistance between the semiconductor layer 110 and the first electrode layer 140 is lowered, and the quantity of heat that may be generated at an interface between the semiconductor layer 110 and the first electrode layer 140 may decrease.

The second electrode layer 150 may include a second silicide layer 152 and a second conductive layer 154. The second silicide layer 152 may be disposed between the semiconductor layer 110 and the second conductive layer 154. The electrical resistance of the second silicide layer 152 may be smaller than the electrical resistance of the second conductive layer 154. Therefore, the speed of movement of carriers (e.g., electrons or holes) through the semiconductor layer 110 may be faster than when the second conductive layer 154 is in direct contact with the semiconductor layer 110. In addition, by providing the second silicide layer 152, the contact resistance between the semiconductor layer 110 and the second electrode layer 150 is lowered, and the quantity of heat that may be generated at the interface between the semiconductor layer 110 and the second electrode layer 150 may decrease.

The first silicide layer 142 and the second silicide layer 152 may each include a metal silicide layer. For example, the metal silicide layer may include a metal and silicon, and the metal may include a metal material such as titanium (Ti), nickel (Ni), molybdenum (Mo), tungsten (W), cobalt (Co), platinum (Pt), hafnium (Hf), tantalum (Ta), copper (Cu), chromium (Cr), ytterbium (Yb), erbium (Er) or palladium (Pd).

The interface between the first silicide layer 142 and the first conductive layer 144, and the interface between the second silicide layer 152 and the second conductive layer 154 may or may not exist.

The first electrode layer 140 includes a first impurity pile-up region R1 in which the impurities 120 are gathered. The first impurity pile-up region R1 may be formed along the interface between the first electrode layer 140 and the semiconductor layer 110. The first impurity pile-up region R1 may be formed along the interface between the first silicide layer 142 and the semiconductor layer 110. That is, the first silicide layer 142 may include the first impurity pile-up region R1. The first impurity pile-up region R1 may be formed on an upper face 110US of the semiconductor layer 110.

The second electrode layer 150 includes a second impurity pile-up region R2 in which the impurities 120 are gathered. The second impurity pile-up region R2 may be formed along the interface between the second electrode layer 150 and the semiconductor layer 110. The second impurity pile-up region R2 may be formed along the interface between the second silicide layer 152 and the semiconductor layer 110. That is, the second silicide layer 152 may include a second impurity pile-up region R2. The second impurity pile-up region R2 may be formed on the upper face 110US of the semiconductor layer 110.

The impurity 120 may include an N-type impurity or a P-type impurity. The P-type impurity may include, but is not limited to, at least one of boron (B) and gallium (Ga). The N-type impurity may include, but is not limited to, at least one of phosphorus (P), arsenic (As), antimony (Sb), and bismuth (Bi).

In the semiconductor device according to some embodiments, the contact resistance between the semiconductor layer 110 and the first electrode layer 140, and the contact resistance between the semiconductor layer 110 and the second electrode layer 150 may be improved by a work function modulation through doping of the impurity 120.

The gate oxide layer 160 may be disposed on the semiconductor layer 110. The gate oxide layer 160 may be disposed between the first electrode layer 140 and the second electrode layer 150. The gate oxide layer 160 may be in contact with the semiconductor layer 110. The gate oxide layer 160 may be in contact with, for example, a part of a side face of the first electrode layer 140 and a part of a side face of the second electrode layer 150. The gate oxide layer 160 may include an insulating material.

In some embodiments, the gate oxide layer 160 may include silicon oxide or silicon oxynitride.

In some embodiments, the gate oxide layer 160 may include a high-k material. The high-k material may include a metal oxide having a higher dielectric constant than silicon oxide. For example, the high-k material may include hafnium oxide, hafnium oxynitride, hafnium silicon oxide, or the like.

The gate oxide layer 160 may include a third impurity pile-up region R3 in which the impurities 120 are gathered. The third impurity pile-up region R3 may be formed along the interface between the gate oxide layer 160 and the semiconductor layer 110. The third impurity pile-up region R3 may be formed on the upper face 110US of the semiconductor layer 110.

The gate electrode 170 may be disposed on the gate oxide layer 160. The gate electrode 170 may include a metal material, a metal alloy, or a conductive oxide.

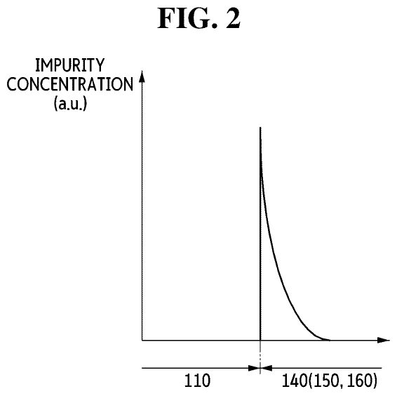

FIG. 2 is a diagram for explaining the first to third impurity pile-up regions of FIG. 1.

Referring to FIGS. 1 and 2, the concentration of the impurity 120 may increase sharply at a boundary between the semiconductor layer 110 and the first electrode layer 140. Also, the concentration of the impurity 120 in the first electrode layer 140 may decrease sharply as it goes away from the semiconductor layer 110.

The concentration distribution of the impurity 120 in the second electrode layer 150 and the gate oxide layer 160 may be similar to the concentration distribution of the impurity 120 in the first electrode layer 140. The concentration of the impurity 120 in the second electrode layer 150 may decrease sharply as it goes away from the semiconductor layer 110. The concentration of the impurity 120 in the gate oxide layer 160 may decrease sharply as it goes away from the semiconductor layer 110. The maximum concentration of the impurity 120 in the gate oxide layer 160 may be smaller than the maximum concentration of the impurity 120 in the first electrode layer 140 and the maximum concentration of the impurity 120 in the second electrode layer 150.

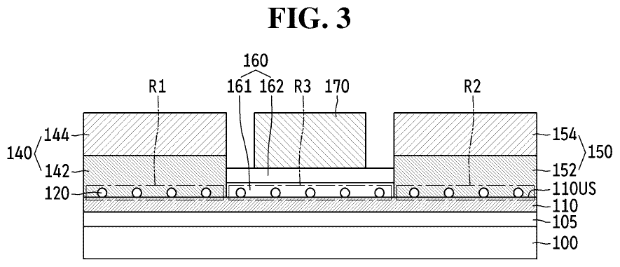

FIG. 3 is a diagram for explaining a semiconductor device according to some embodiments. For convenience of explanation, differences from those described using FIGS. 1 and 2 will be mainly described.

Referring to FIG. 3, in the semiconductor device according to some embodiments, the gate oxide layer 160 may include an interfacial layer 161 and a high-k layer 162.

The interfacial layer 161 may be disposed on the semiconductor layer 110. The high-k layer 162 may be disposed on the interfacial layer 161. The gate electrode 170 may be disposed on the high-k layer 162.

The interfacial layer 161 may include a third impurity pile-up region R3 in which the impurities 120 are gathered.

The interfacial layer 161 and the high-k layer 162 may include different materials from each other. The interfacial layer 161 may include, for example, silicon oxide or silicon oxynitride. The high-k layer 162 may include a high-k material. A dielectric constant of the high-k layer 162 may be higher than a dielectric constant of the interfacial layer 161. The high-k layer 162 may include, for example, hafnium oxide, hafnium oxynitride, or hafnium silicon oxide.

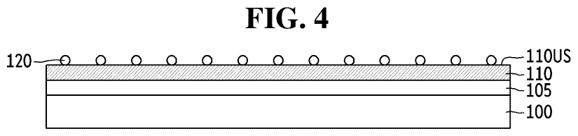

FIGS. 4 to 7 are diagrams for explaining a method for fabricating a semiconductor device according to some embodiments. For convenience of explanation, differences from those explained using FIGS. 1 to 3 will be mainly explained.

Referring to FIG. 4, a semiconductor layer 110 including a two-dimensional semiconductor material may be formed on the insulating layer 105. The process of forming the semiconductor layer 110 may be performed, for example, inside a vacuum chamber.

Next, impurities 120 may be implanted onto the semiconductor layer 110. The impurities 120 may be implanted onto the upper face 100US of the semiconductor layer 110.

The impurities 120 may be performed through a gas vapor phase doping process. The doping gas used in the process of implanting the impurities 120 onto the semiconductor layer 110 may be, for example, PH3, BF₃, B₂H₆, NO₂, SO₂, MoO₃, etc. The doping gas may be selected in various ways depending on the doping purpose.

For example, the surface of the N-type semiconductor layer 110 may be doped with P-type impurities 120, using PH3 doping gas at 400 degrees or more.

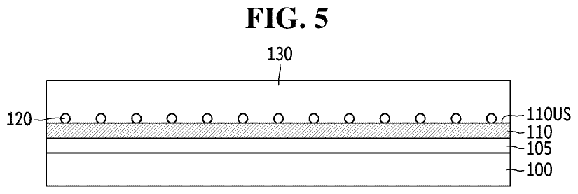

Referring to FIG. 5, a capping layer 130 may be formed on the semiconductor layer 110. The capping layer 130 may cover the semiconductor layer 110. The process of implanting the impurity 120 onto the semiconductor layer 110 and the process of forming the capping layer 130 may be performed in situ. The process of forming the capping layer 130 may be performed, for example, inside a vacuum chamber.

The capping layer 130 may include, for example, silicon. The capping layer 130 may include, for example, amorphous silicon.

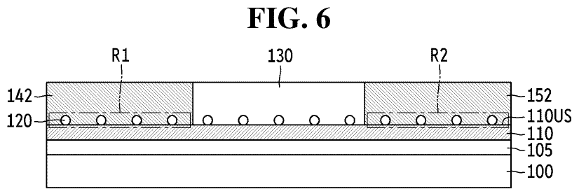

Referring to FIG. 6, a first silicide layer 142 and a second silicide layer 152 may be formed on the semiconductor layer 110. The first silicide layer 142 and the second silicide layer 152 may be formed through a silicidation process of the capping layer 130. Accordingly, the first silicide layer 142 may include a first impurity pile-up region R1 including the impurity 120, and the second silicide layer 152 may include a second impurity pile-up region R2 including the impurity 120.

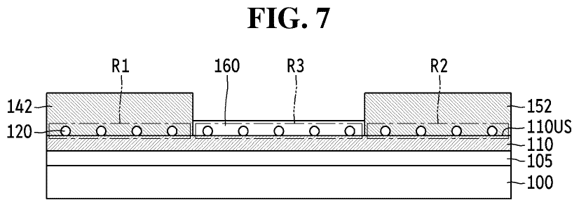

Referring to FIGS. 6 and 7, a gate oxide layer 160 may be formed on the semiconductor layer 110. The gate oxide layer 160 may be formed between the first silicide layer 142 and the second silicide layer 152.

In some embodiments, the gate oxide layer 160 may be formed through an oxidation process of the capping layer 130. The gate oxide layer 160 may include silicon oxide. The gate oxide layer 160 may include a third impurity pile-up region R3 including the impurity 120. The third impurity pile-up region R3 may include the impurity 120 formed in FIG. 5. In the process of forming the gate oxide layer 160 through the oxidation process of the capping layer 130, the concentration of the impurity 120 in the capping layer 130 may decrease. The maximum concentration of the impurity 120 in the gate oxide layer 160 may be smaller than the maximum concentration of the impurity 120 in the first silicide layer 142 and the maximum concentration of the impurity 120 in the second silicide layer 152.

In some embodiments, the capping layer 130 may be removed, and the gate oxide layer 160 may be formed in a space from which the capping layer 130 was removed. A cleaning process may be performed on the semiconductor layer 110 before the gate oxide layer 160 is formed after the capping layer 130 is removed.

The process of forming the first silicide layer 142 and the second silicide layer 152 may be performed before or after the process of forming the gate oxide layer 160.

Next, referring to FIG. 1, a first conductive layer 144 may be formed on the first silicide layer 142. A second conductive layer 154 may be formed on the second silicide layer 152. A gate electrode 170 may be formed on the gate oxide layer 160.

The impurities 120 implanted onto the semiconductor layer 110 may be desorbed due to thermal budget in a high-temperature process, for example, a process performed at 200 degrees Celsius or higher.

However, in the method for fabricating the semiconductor device according to some embodiments, the capping layer 130 is formed after implanting the impurities 120 onto the semiconductor layer 110. As a result, the thermal budget may decrease in the fabricating process of the semiconductor device by the capping layer 130, and the desorption of the impurity 120 may be suppressed. Therefore, the impurity 120 may be stably doped onto the semiconductor layer 110.

In addition, the first silicide layer 142 and the second silicide layer 152 may be formed through a silicidation process of the capping layer 130. Therefore, the resistance of the first electrode layer 140 and the second electrode layer 150 may be improved.

In addition, the gate oxide layer 160 may be formed, by utilizing the capping layer 130.

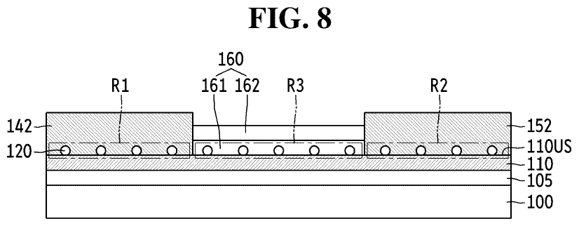

FIG. 8 is a diagram for explaining a method for fabricating a semiconductor device according to some embodiments. For reference, FIG. 8 is a diagram subsequent to FIG. 6.

Referring to FIGS. 6 and 8, a gate oxide layer 160 including an interfacial layer 161 and a high-k layer 162 may be formed.

The interfacial layer 161 may be formed through an oxidation process of the capping layer 130. The interfacial layer 161 may include silicon oxide. The high-k layer 162 may be formed on the interfacial layer 161. Therefore, the interfacial layer 161 may include a third impurity pile-up region R3 including the impurity 120. The interfacial layer 161 may serve as seeding when forming the high-k layer 162. That is, the difficulty of the process of forming the high-k layer 162 may be improved or reduced.

Next, referring to FIG. 3, a first conductive layer 144 may be formed on the first silicide layer 142. A second conductive layer 154 may be formed on the second silicide layer 152. A gate electrode 170 may be formed on the gate oxide layer 160.

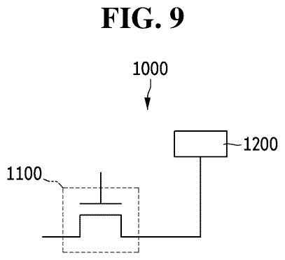

FIG. 9 is a diagram for explaining an electronic element according to some embodiments.

Referring to FIG. 9, the electronic element 1000 may include a switching element 1100, and a data storage unit 1200 connected thereto. The switching element 1100 may include a transistor. The switching element 1100 may include one of the semiconductor devices described in FIGS. 1 to 3.

The data storage unit 1200 may include a data storage unit used in a volatile or non-volatile memory element. The data storage unit 1200 may include a capacitor, and may include a magnetic resistance layer or a phase change layer. The electronic element 1000 may be a memory device.

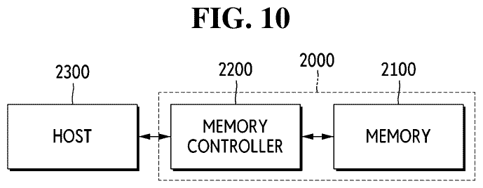

FIG. 10 is a diagram for explaining an electronic system according to some embodiments.

Referring to FIG. 10, an electronic system 2000 may include a memory 2100 and a memory controller 2200. The memory controller 2200 may control the memory 2100 to read data from and/or write data to the memory 2100 in response to a request from the host 2300.

In some embodiments, the memory 2100 may include the electronic element 1000 of FIG. 9. In some embodiments, the memory 2100 and the memory controller 2200 of the electronic system 2000 may include a switching element, and the switching element may include a semiconductor device described using FIGS. 1 to 3.

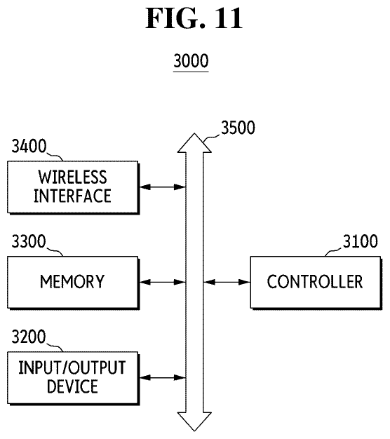

FIG. 11 is a diagram for explaining an electronic system according to some embodiments.

Referring to FIG. 11, an electronic system 3000 may constitute a wireless communication device or a device capable of transmitting and/or receiving information under a wireless environment. The electronic system 3000 includes a controller 3100, an input/output device 3200, a memory 3300, and a wireless interface 3400, each of which is interconnected via a bus 3500.

The controller 3100 may include at least one of a microprocessor, a digital signal processor, or a processing device similar thereto.

The input/output device 3200 may include at least one of a keypad, a keyboard, or a display.

The memory 3300 may be used to store instructions executed by the controller 3100. For example, the memory 3300 may be used to store user data. The memory 3300 may include the electronic element 1000 of FIG. 9.

The components 3100, 3200, 3300, and 3400 included in the electronic system 3000 may include a switching element, and the switching element may include the semiconductor devices described using FIGS. 1 to 3.

The electronic system 3000 may use the wireless interface 3400 to transmit and receive data through a wireless communication network. A wireless interface 3103 may include an antenna and/or a wireless transceiver. In some embodiments, the electronic system 3000 may be used for a communication interface protocol of a third generation communication system, for example, a code division multiple access (CDMA), a global system for mobile communications (GSM), a north American digital cellular (NADC), an extended-time division multiple access (E-TDMA), and/or a wide band code division multiple access (WCDMA).

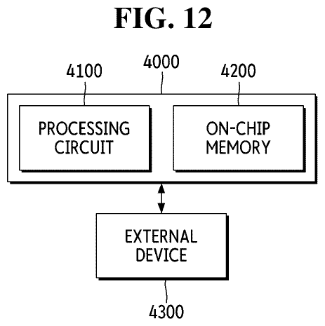

FIG. 12 is a diagram for explaining a neuromorphic device according to some embodiments.

Referring to FIG. 12, a neuromorphic device 4000 may include a processing circuit 4100 and an on-chip memory 4200.

The processing circuit 4100 may be configured to control functions for driving the neuromorphic device 4000. For example, the processing circuit 4100 may control the neuromorphic device 4000 by executing the program stored in the on-chip memory 4200 of the neuromorphic device 4000. The on-chip memory 4200 may include the semiconductor device described using FIGS. 1 to 3.

The processing circuit 4100 may include hardware such as a logic circuit, a combination of hardware and software such as a processor that executes software, or a combination thereof. For example, the processor may include a central processing unit (CPU), a graphics processing unit (GPU), an application processor (AP) in the neuromorphic device 4000, an arithmetic logic unit (ALU), a digital processor, a microcomputer, a field programmable gate array (FPGA), a system-on-chip (SoC), a programmable logic unit, a microprocessor, an application-specific integrated circuit (ASIC), and the like.

The processing circuit 4100 may also read and write various types of data in the external device 4300 and execute the neuromorphic device 4000, by the use of the data. The external device 4300 may include an external memory device and/or a sensor array equipped with an image sensor (e.g., a CMOS image sensor circuit).

The neuromorphic device 4000 may be applied to a machine learning system. The machine learning system may utilize, for example, a convolutional neural network (CNN), a deconvolutional neural network, a recurrent neural network (RNN) selectively including a long short-term memory device (LSTM) and/or a gated recurrent unit (GRU), and various artificial neural network organizations and processing models including a stacked neural network (SNN), a state-space dynamic neural network (SSDNN), a deep belief network (DBN), a generative adversarial networks (GAN), and/or a restricted Boltzmann machines (RBM).

Such a machine learning system may include, for example, a linear regression and/or a logistic regression, statistical clustering, a Bayesian classification, decision trees, a dimensionality reduction such as principal component analysis, and other types of machine learning models such as expert systems, and/or combinations thereof including ensemble techniques such as random forest. Such a machine learning model may be used to provide various services such as an image classification service, a user authentication service based on biometric information or biometric data, an advanced driver assistance system (ADAS), a voice assistant service, and an automatic speech recognition (ASR) service, and may be installed and executed in other electronic devices.

Although the embodiments of the present disclosure have been described above with reference to the accompanying drawings, the present disclosure is not limited to the above embodiments, and may be fabricated in various different forms. Those skilled in the art will appreciate that the present disclosure may be embodied in other specific forms without changing the technical spirit or essential features of the present disclosure. Accordingly, the above-described embodiments should be understood in all respects as illustrative and not restrictive.

What is claimed is:

1. A semiconductor device comprising:
a semiconductor layer including a two-dimensional semiconductor material; and
an electrode layer on the semiconductor layer,
wherein the electrode layer includes a first impurity pile-up region in which impurities are gathered.

2. The semiconductor device of claim 1,
wherein the electrode layer includes a silicide layer and a conductive layer on the silicide layer, and
the silicide layer includes the first impurity pile-up region.

3. The semiconductor device of claim 2,
wherein the first impurity pile-up region is along an interface between the semiconductor layer and the silicide layer.

4. The semiconductor device of claim 1, further comprising:
a gate oxide layer on the semiconductor layer, and
a gate electrode on the gate oxide layer,
wherein the gate oxide layer includes silicon oxide.

5. The semiconductor device of claim 1, further comprising:
a gate oxide layer on the semiconductor layer, and
a gate electrode on the gate oxide layer,
wherein the gate oxide layer includes a high-k material.

6. The semiconductor device of claim 1, further comprising:
a gate oxide layer on the semiconductor layer, and
a gate electrode on the gate oxide layer,
wherein the gate oxide layer includes an interfacial layer and a high-k layer.

7. The semiconductor device of claim 1, further comprising:
a gate oxide layer on the semiconductor layer, and
a gate electrode on the gate oxide layer,
wherein the gate oxide layer includes a second impurity pile-up region in which impurities are gathered.

8. The semiconductor device of claim 7,
wherein the second impurity pile-up region is along an interface between the semiconductor layer and the gate oxide layer.

9. A method for fabricating a semiconductor device, the method comprising:
forming a semiconductor layer including a two-dimensional semiconductor material;
implanting impurities onto the semiconductor layer; and
forming a capping layer which covers the semiconductor layer into which the impurities are implanted.

10. The method for fabricating the semiconductor device of claim 9,
wherein the implanting impurities is performed through a gas-phase doping process.

11. The method for fabricating the semiconductor device of claim 10,
wherein the gas-phase doping process uses PH3, BF₃, B₂H₆, NO₂, SO₂ or MoO₃.

12. The method for fabricating the semiconductor device of claim 9,
wherein the capping layer includes silicon.

13. The method for fabricating the semiconductor device of claim 12, further comprising:
forming a silicide layer in a part of the capping layer.

14. The method for fabricating the semiconductor device of claim 13, further comprising:
forming a conductive layer on the silicide layer.

15. The method for fabricating the semiconductor device of claim 12, further comprising:
oxidizing a part of the capping layer to form a gate oxide layer.

16. The method for fabricating the semiconductor device of claim 15, further comprising:
forming a gate electrode on the gate oxide layer.

17. The method for fabricating the semiconductor device of claim 9, further comprising:
removing a part of the capping layer to define a space in the capping layer from which the part of the capping layer that is removed, and
forming a gate oxide layer and a gate electrode on the semiconductor layer, the gate oxide layer being formed in the space in the capping layer from which the part of the capping layer is removed and the gate electrode being formed on the gate oxide layer.

18. The method for fabricating the semiconductor device of claim 9,
wherein the implanting impurities and the forming the capping layer are performed in situ.

19. The method for fabricating the semiconductor device of claim 9,
wherein the semiconductor layer includes graphene, MoS₂, WS₂, WSe₂, hBN, or black phosphorus.

20. A semiconductor device comprising:
a semiconductor layer including a two-dimensional semiconductor material;
a first conductive layer on the semiconductor layer;
a second conductive layer on the semiconductor layer;
a first silicide layer between the semiconductor layer and the first conductive layer; and
a second silicide layer between the semiconductor layer and the second conductive layer,
wherein the first silicide layer includes a first impurity pile-up region along an interface between the semiconductor layer and the first silicide layer, and
the second silicide layer includes a second impurity pile-up region along an interface between the semiconductor layer and the second silicide layer.
